(19) United States
(12) Patent Application Publication
(10) Pub. No.: US 2005/0082562 A1
(43) Pub. Date: Apr. 21, 2005

(54) High efficiency nitride based light emitting device

(75) Inventors: Chen Ou, Hsin-Chu City (TW); Biau-Dar Chen, Hsin-Chu City (TW); Shane-Shyan Wey, Hsin-Chu City (TW); Yen-Ting Tsai, Hsin-Chu City (TW)

Correspondence Address: NORTH AMERICA INTERNATIONAL PATENT OFFICE (NAIPC), P.O. BOX 506, MERRIFIELD, VA, 22116, US

(73) Assignee: EPISTAR CORPORATION

(21) Appl. No.: 10/684,392

(22) Filed: Oct. 15, 2003

(51) Int. Cl. H01L 33/00

(52) U.S. Cl. 257/103

(57) ABSTRACT

A nitride light emitting device includes a substrate, a first nitride semiconductor stack formed above the substrate, the first nitride semiconductor stack having an epitaxial surface and a first rough surface, a distance from the epitaxial surface to the substrate being not less than a distance from the rough surface to the substrate, a nitride emitting layer formed on the epitaxial surface, and a second nitride semiconductor stack formed on the nitride emitting layer for promoting the efficiency of capturing light emitted from an LED.

### BACKGROUND OF INVENTION

1. Field of the Invention

The present invention relates to a light emitting diode (LED) and related method, and more particularly, to a nitride light emitting device and related method.

2. Description of the Prior Art

The light emitting diode (LED) has been widely used in various fields. For instance, light emitting diodes are capable of being installed in optical display devices, traffic lights, data storage devices, communication devices, illuminative equipment, and medical equipment.

LED light travels in each direction instead of focusing on one place. However, the light generated from an LED is not easily emitted out from the LED. According to Snell's law, only light emitted at an angle within the critical angle θ c would be completely emitted out, and other light would be reflected and absorbed. In other words, the angle of LED light must be within a cone of 2 θ c to be completely emitted out. Light emitted at an angle larger than 2 θ c is reflected. When LED light travels from a material with a high refractive index to the material with a low refractive index, the angle of light emitted is limited due to the effect of refractive indexes. Therefore, an important issue is how to improve the efficiency of light emission.

In order to solve the problem mentioned above, a method for improving the efficiency of light extraction is disclosed in Taiwan PN 472400. This method for manufacturing an LED includes steps of forming a rough surface over the top layer of the LED, and enhancing the angle of total reflection to cause almost all light to be emitted for improving the illumination effect of the LED. However, the disclosed structure only promotes the efficiency of light extraction for light that is emitted forward the area over the emitting layer. However, beneath the emitting layer, where the light is reflecting between the N-type semiconductor layer and the substrate, such method and the light emitting to the side of the LED, cannot improve the light extraction efficiency.

### SUMMARY OF INVENTION

It is therefore a primary objective of the claimed invention to provide a nitride light emitting device and related method to solve the above-mentioned problem. The nitride light emitting device comprises a substrate; a first nitride semiconductor layer formed over the substrate, the first nitride semiconductor layer further comprising an epitaxial surface and a rough surface, a distance from the epitaxial surface to the substrate being not less than a distance from the rough surface to the substrate; a nitride emitting layer formed on the epitaxial surface; and a second nitride semiconductor layer formed on the nitride emitting layer.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

The file of this patent contains at least one drawing executed in color. Copies of this patent with color drawing(s) will be provided by the Patent and Trademark Office upon request and payment of the necessary fee.

FIG. 1A is an illustration of light path in a conventional LED.

FIG. 1B is an illustration of light path in the present invention LED.

FIG. 2 shows a first embodiment of the present invention nitride light emitting device.

FIG. 3 shows a second embodiment of the present invention nitride light emitting device.

FIG. 4 shows a third embodiment of the present invention nitride light emitting device.

FIG. 5 shows a fourth embodiment of the present invention nitride light emitting device.

FIG. 6 shows a fifth embodiment of the present invention nitride light emitting device.

FIG. 7 shows roughness in a conventional LED.

FIG. 8 shows roughness in the present invention LED.

FIG. 9 shows a distribution of the roughness of the present invention LED light corresponding to the brightness.

### DETAILED DESCRIPTION

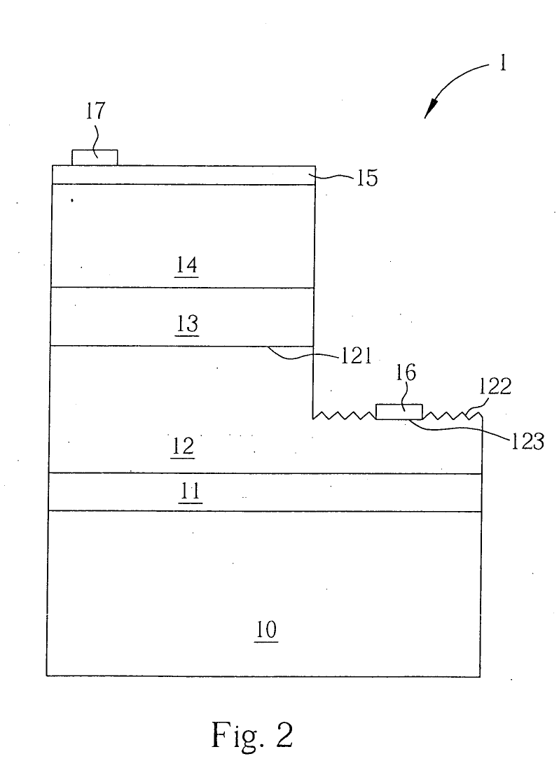

Please refer to FIG. 2. FIG. 2 illustrates a first embodiment of the present invention nitride light emitting device 1. The nitride light emitting device 1 comprises a sapphire substrate 10; a nitride buffer layer 11 formed over the sapphire substrate 10; a N-type nitride semiconductor stack 12 formed over the nitride buffer layer 11, wherein an epitaxial surface 121, a rough surface 122, and a N-type contact area 123 are included on an upper surface of the N-type nitride semiconductor stack 12; a nitride multiple quantum-well structure emitting layer 13 formed over the epitaxial surface 121; a P-type nitride semiconductor stack 14 formed over the nitride multiple quantum-well structure emitting layer 13; a transparent conductive metal layer 15 formed over the P-type nitride semiconductor stack 14; a N-type electrode 16 formed over the N-type contact area 123; and a P-type electrode 17 formed over the transparent conductive metal layer 15.

There are many methods for manufacturing the nitride light emitting device 1. The first method includes: forming the nitride buffer layer 11, the N-type nitride semiconductor stack 12, the nitride multiple quantum-well structure emitting layer 13, and the P-type nitride semiconductor stack 14 over the sapphire substrate 10 by epitaxial growth; etching part of the P-type nitride semiconductor stack 14, the nitride multiple quantum-well structure emitting layer 13, and the N-type nitride semiconductor stack 12 by performing an inductive coupling plasma (ICP) dry etching process for forming a flat surface on the N-type nitride semiconductor stack 12, wherein a part of the flat surface is used for forming a N-type contact area 123; and etching the remaining of the flat surface by performing ICP dry etching process for forming the rough surface 122.

The second method for manufacturing the nitride light emitting device 1 includes: forming the nitride buffer layer 11, the N-type nitride semiconductor stack 12, the nitride multiple quantum-well structure emitting layer 13, and the P-type nitride semiconductor stack 14 over a sapphire substrate 10 by epitaxial growth; etching part of the P-type nitride semiconductor stack 14, the nitride multiple quantum-well structure emitting layer 13, and the N-type nitride semiconductor stack 12 by an ICP dry etching process for forming a rough surface on the N-type nitride semiconductor stack 12; selecting a part of the rough surface used for forming a N-type contact area 123; covering the remaining rough surface; exposing the selected rough surface; and etching the selected rough surface to make it flat by performing an ICP dry etching process for forming the N-type contact area 123.

The third method for manufacturing the nitride light emitting device 1 includes: forming the nitride buffer layer 11, the N-type nitride semiconductor stack 12, the nitride multiple quantum-well structure emitting layer 13, and the P-type nitride semiconductor stack 14 over the sapphire substrate 10 by epitaxial growth; etching part of the P-type nitride semiconductor stack 14, the nitride multiple quantum-well structure emitting layer 13, and the N-type nitride semiconductor stack 12 by performing an ICP dry etching process for forming a flat surface on the N-type nitride semiconductor stack 12; covering a part of the flat surface for forming a N-type contact area 123; and etching the remaining uncovered flat surface to become rough by performing a wet etching process (such as that using a hot phosphoric acid solution) for forming the rough surface 122.

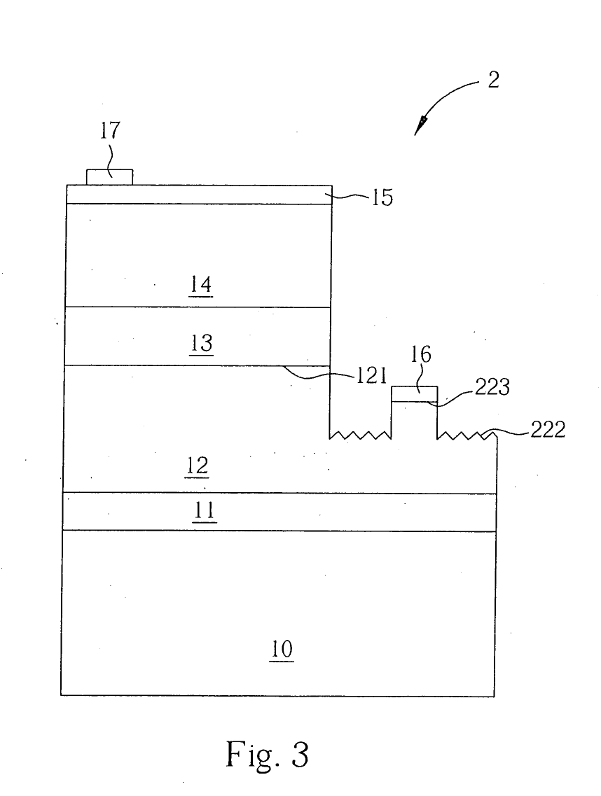

Please refer to FIG. 3. FIG. 3 illustrates a second embodiment of the present invention nitride light emitting device 2. A key difference from the first embodiment is that a rough surface 222 and an N-type contact area 223 are not on the same plane, the rough surface 222 being lower than the N-type contact area 223. Alternatively, the rough surface 222 can be higher than the N-type contact area 223.

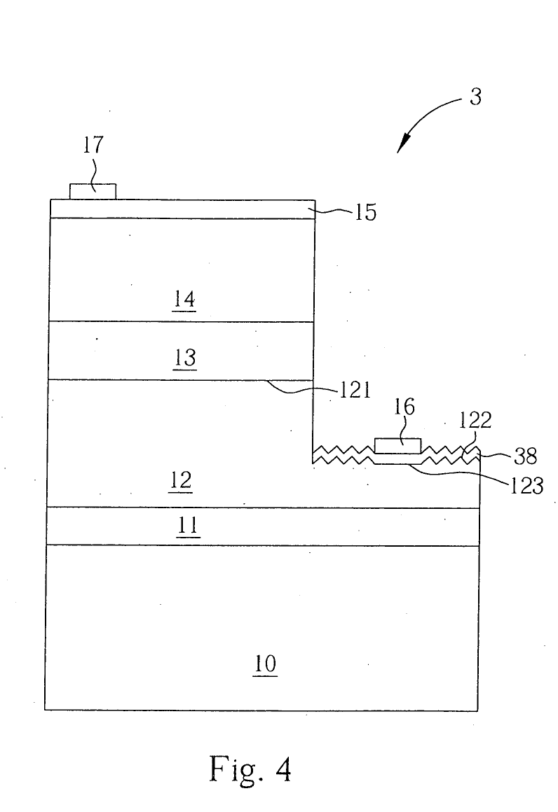

Please refer to FIG. 4. FIG. 4 illustrates a third embodiment of the present invention nitride light emitting device 3. A key difference from the first embodiment is that a transparent oxidizing conductive layer 38 is formed over the rough surface 122 and the N-type contact area 123 for promoting N-type current diffusion.

Another embodiment of the present invention nitride light emitting device 4 (not shown) is different from the first embodiment in that a transparent conductive oxide layer substituting for the transparent conductive metal layer is formed over the P-type nitride semiconductor stack 14. The penetration of the transparent conductive oxide layer is better than that of the transparent conductive metal layer and thus light emitting efficiency can be further improved.

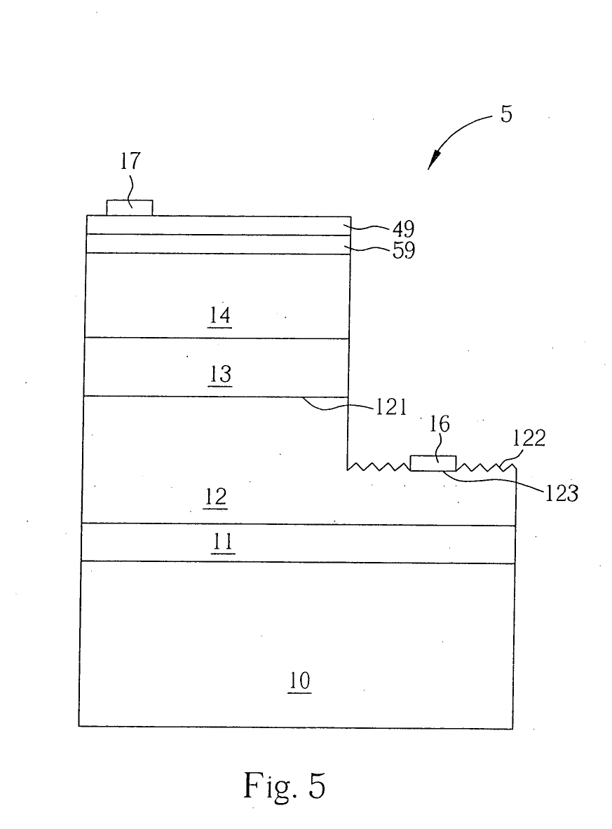

Please refer to FIG. 5. FIG. 5 illustrates a fourth embodiment of the present invention nitride light emitting device 5. A key difference compared to the nitride light emitting device 4 is that an N-type reverse tunneling contact layer 59 with high concentration is formed between the P-type nitride semiconductor stack 14 and the transparent conductive oxide layer 49. The thickness of the N-type reverse tunneling contact layer 59 is less than 10 nm and the carrier concentration is more than 1*10\hat{ }19 cm\hat{ }−3. It is different to form a good Ohmic contact between the P-type nitride semiconductor stack 14 and the transparent conductive oxide layer 49, and thus forming the N-type reverse tunneling contact layer 59 with high concentration can form a good Ohmic contact to the transparent conductive oxide layer 49. When the LED is working under forward bias, the interface between the N-type reverse tunneling contact layer 59 and the P-type nitride semiconductor stack 14 is under reverse bias and forms a depletion region. Moreover, since the N-type reverse tunneling contact layer 59 is relatively thin, the carrier of the transparent conductive oxide layer 49 can easily penetrate into the P-type nitride semiconductor stack 14 by the tunnel effect thus preserving the characteristics of low bias.

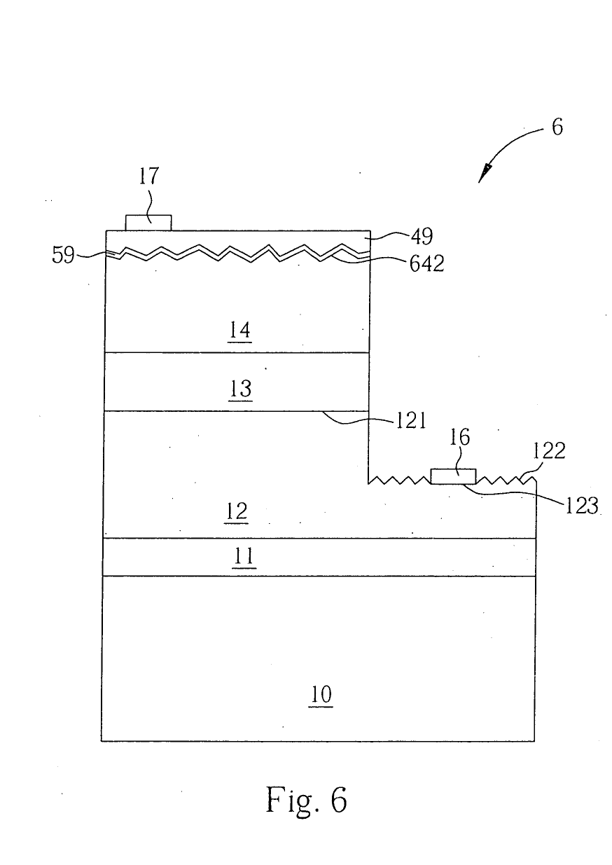

Please refer to FIG. 6. FIG. 6 illustrates a fifth embodiment of the present invention nitride light emitting device 6. The nitride light emitting device 6 comprises the sapphire substrate 10; the nitride buffer layer 11 formed over the sapphire substrate 10; the N-type nitride semiconductor stack 12 formed over the nitride buffer layer 11, wherein the epitaxial surface 121, the rough surface 122, and the N-type contact area 123 are included on an upper surface of the N-type nitride semiconductor stack 12; the N-type electrode 16 formed over the N-type contact area 123; the nitride multiple quantum-well structure emitting layer 13 formed over the epitaxial surface 121; the P-type nitride semiconductor stack 14 formed over the nitride multiple quantum-well structure emitting layer 13, wherein a rough surface 642 is formed over the P-type nitride semiconductor stack 14; the N-type reverse tunneling contact layer 59 with high concentration formed over the P-type nitride semiconductor stack 14, wherein the thickness of the N-type reverse tunneling contact layer 59 is less than 10 nm and the carrier concentration is more than 1*10\hat{ }19 cm\hat{ }−3; the transparent conductive oxide layer 49 formed over the N-type reverse tunneling contact layer 59; and the P-type electrode 17 formed over the transparent conductive oxide layer 49. Due to the rough surfaces 122 and 642, the extraction efficiency of the emitting light is further improved.

A method for manufacturing the nitride light emitting device 6 includes: forming the nitride buffer layer 11, the N-type nitride semiconductor stack 12, the nitride multiple quantum-well structure emitting layer 13, and the P-type nitride semiconductor stack 14 over the sapphire substrate 10 by epitaxial growth; etching part of the P-type nitride semiconductor stack 14, the nitride multiple quantum-well structure emitting layer 13, and the N-type nitride semiconductor stack 12 by performing an ICP dry etching process for forming a flat surface on the N-type nitride semiconductor stack 12, wherein a part of the flat surface is used for forming the N-type contact area 123; and etching the remaining part of the flat surface by performing a second ICP dry etching process for forming the rough surface 122.

A method for forming the rough surface 642 of the P-type nitride semiconductor stack 14 of the nitride light emitting device 6 comprises: after epitaxial growth, etching the P-type nitride semiconductor stack 14 by performing an ICP dry etching process. Another method for forming the rough surface 642 of the P-type nitride semiconductor stack 14 comprises: while the P-type nitride semiconductor stack 14 is being formed by epitaxial growth, changing conditions of epitaxial growth such as growth ambient, temperature, pressure, V/III ratio, and so forth.

The N-type contact area of the nitride light emitting devices mentioned above is provided to avoid the effect of poor contact due to rough surface, which causes the forward voltage of the device to increase. Therefore, forming a flat area of the N-type contact area improves the Ohmic contact and thus avoids the problem of high forward voltage.

From Table 1, the light emitting efficiency of the present invention nitride light emitting devices compared with that of conventional LED is improved by 37% up to 154%. Therefore the present invention LED can greatly enhance the efficiency of devices in which it is used.

TABLE 1

| | Brightness, Iv (mcd) | Improvement |
|---|---|---|
| Conventional LED | 35 | — |
| Present invention LED 1 | 48 | 37% |
| Present invention LED 5 | 68 | 94% |
| Present invention LED 6 | 89 | 154% |

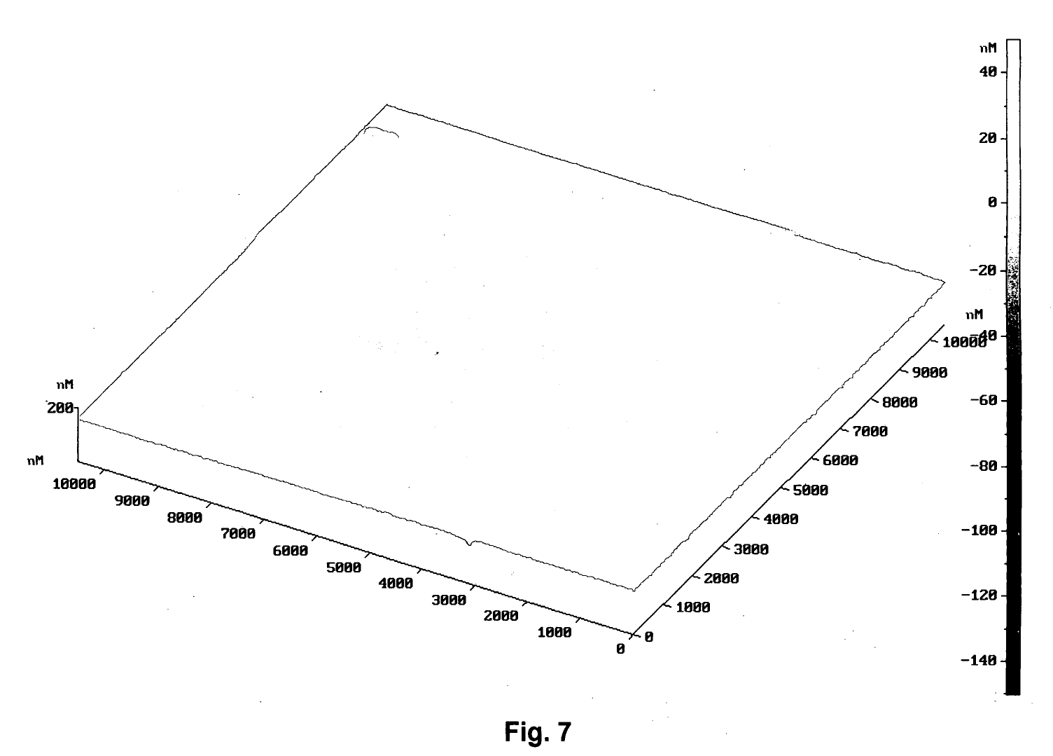

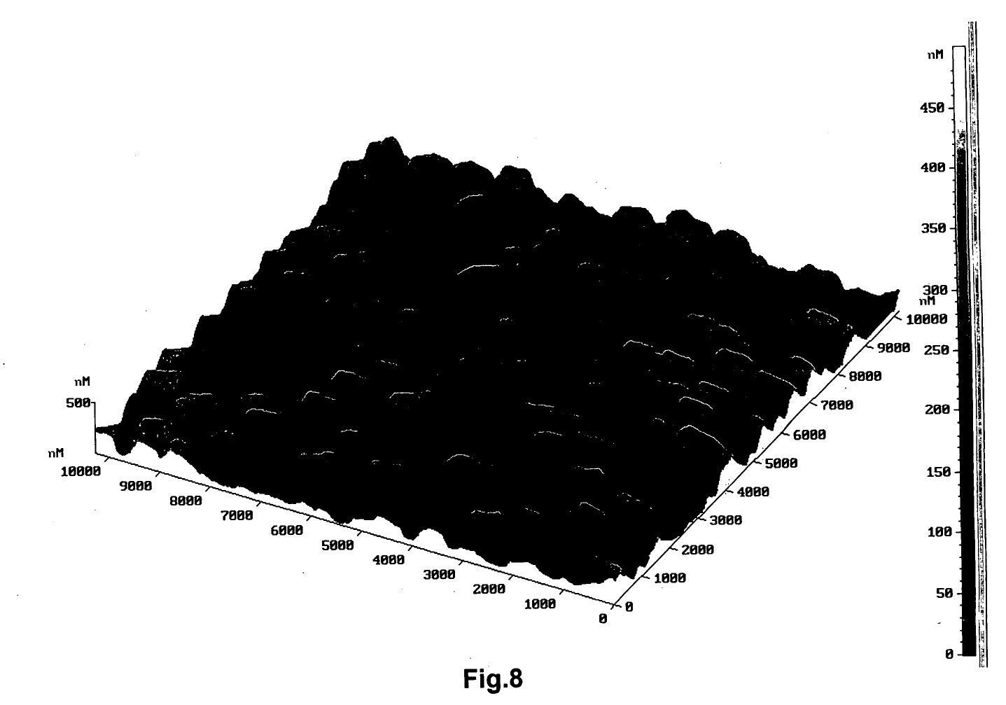

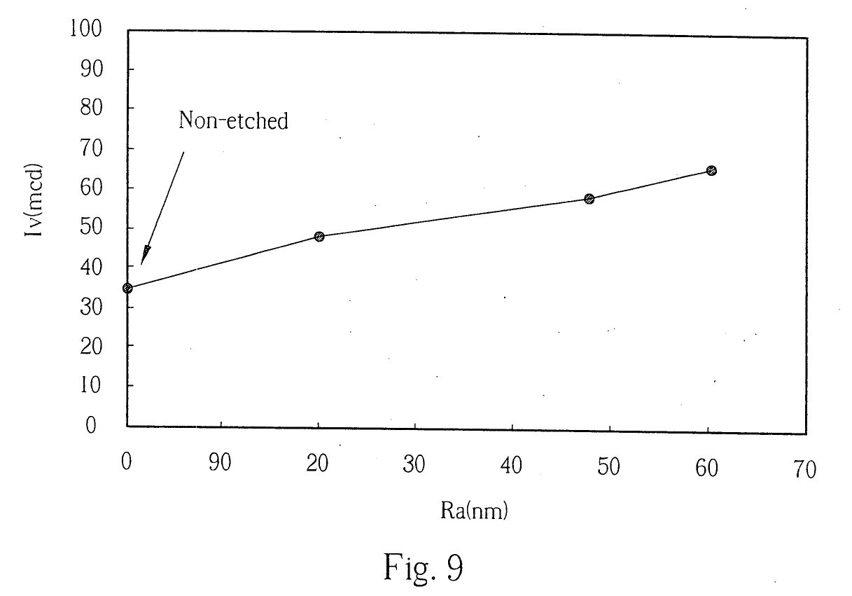

The roughness (Ra) of the rough surface is measured by an atomic force microscope (AFM). The Ra value of the nitride light emitting device 1 before etching (the same as a conventional LED) is within 1 nm (please refer to FIG. 7). After etching, changes of Iv corresponding to the different Ra values of the rough surface 122, which are 20 nm, 48 nm, and 60 nm (please refer to FIG. 8), are measured. Please refer to FIG. 9, when the roughness is increasing, the corresponding Iv is also increasing. For instance, the brightness for the non-etched surface of 35 mcd increases up to 48 mcd (Ra=20 nm), 58 mcd (Ra=48 nm), and 66 mcd (Ra=60 nm). According to these results, the rough surface of the present invention promotes the extraction efficiency of the emitting light and hence increase the brightness of the LED.

In the aforementioned embodiments, the sapphire substrate can also be replaced with at least one material selected from a group consisting of GaN, AlN, SiC, GaAs, GaP, Si, ZnO, MgO, and glass. The nitride buffer layer can be at least one material selected from a group consisting of AlN, GaN, AlGaN, InGaN, and AlInGaN. The N-type nitride semiconductor stack can be at least one material selected from a group consisting of AlN, GaN, AlGaN, InGaN, and AlInGaN. The nitride multiple quantum-well structure emitting layer can be at least one material selected from a group consisting of GaN, InGaN, and AlInGaN. The P-type nitride semiconductor stack can be at least one material selected from a group consisting of AlN, GaN, AlGaN, InGaN, and AlInGaN. The transparent conductive metal layer can be at least one material selected from a group consisting of Ni/Au, NiO/Au, Ta/Au, TiWN, and Ti. The transparent conductive oxidelayer can be at least one material selected from a group consisting of indium tin oxide, cadmium tin oxide, antimony tin oxide, zinc aluminum oxide, and zinc tin oxide. The ICP dry etching process can be replaced with sputter etching, ion beam etching, plasma etching, or reactive ion etching (RIE) process.

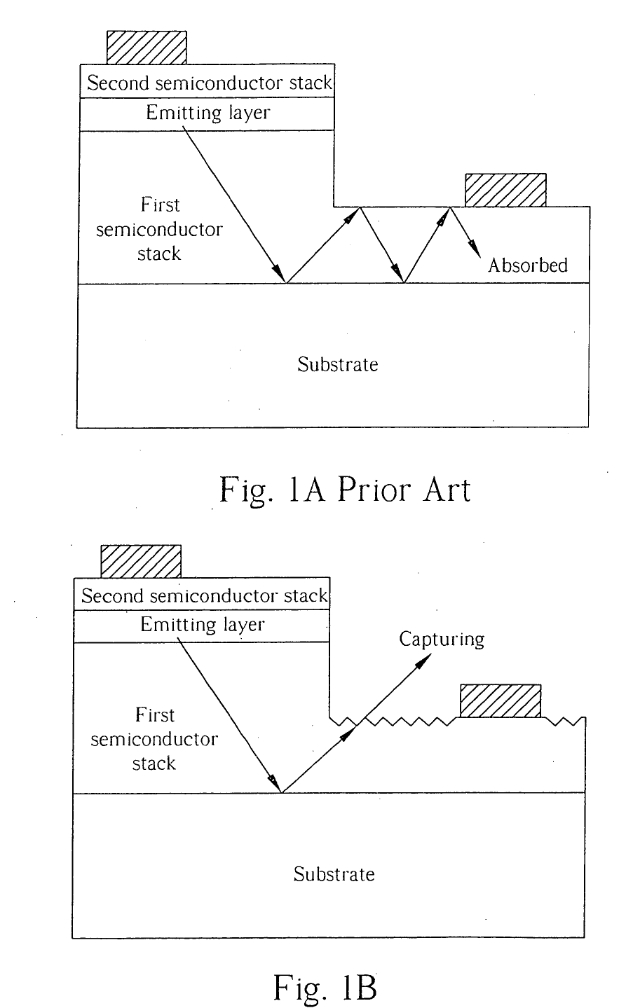

In the prior art, which includes no rough surface, light emitted from the nitride emitting layer easily travels inside the semiconductor layer and is totally reflected between the substrate and the semiconductor layer and between the interface of air and the semiconductor layer. Such light is easily absorbed inside the semiconductor and cannot be emitted after several instances of total reflection, and thus, this reduces the extraction efficiency of light to be emitted (as shown in FIG. 1A). In the present invention, the rough surface of the first nitride semiconductor can reduce the total reflection effect and thus promote the extraction efficiency of external quantum emitting light and hence improve the efficiency of the LED (as shown in FIG. 1B).

Those skilled in the art will readily observe that numerous modifications and alterations of the device may be made while retaining the teachings of the invention. Accordingly, the above disclosure should be construed as limited only by the metes and bounds of the appended claims.

1. A nitride light emitting device comprising:
a substrate;
a first nitride semiconductor stack formed above the substrate, the first nitride semiconductor stack having an epitaxial surface and a first rough surface, a distance from the epitaxial surface to the substrate being not less than a distance from the rough surface to the substrate;
a nitride emitting layer formed on the epitaxial surface; and
a second nitride semiconductor stack formed on the nitride emitting layer.

2. The nitride light emitting device of claim 1 wherein the first nitride semiconductor stack comprises a nitride buffer layer formed on the substrate, and a first nitride contact layer formed on the nitride buffer layer.

3. The nitride light emitting device of claim 1 further comprising a first electrode formed above a first contact area of the first nitride semiconductor stack.

4. The nitride light emitting device of claim 3 further comprising a first transparent conductive layer formed between the first contact area and the first electrode.

5. The nitride light emitting device of claim 3 further comprising a first transparent conductive layer formed on the first contact area and the rough surface of the first nitride semiconductor stack.

6. The nitride light emitting device of claim 3 wherein a roughness of the first contact area is not greater than a roughness of the first rough surface.

7. The nitride light emitting device of claim 1 further comprising a reverse tunneling contact layer formed on the second nitride semiconductor stack, the reverse tunneling contact layer and the second nitride semiconductor stack being formed by opposite types of materials.

8. The nitride light emitting device of claim 7 wherein the reverse tunneling contact layer has a super lattice structure.

9. The nitride light emitting device of claim 8 further comprising a second transparent conductive layer formed on the reverse tunneling contact layer.

10. The nitride light emitting device of claim 1 wherein the second nitride semiconductor stack has a second rough surface and a second contact area.

11. The nitride light emitting device of claim 10 further comprising a second electrode formed above the second contact area of the second nitride semiconductor stack.

12. The nitride light emitting device of claim 1 wherein the first rough surface of the first nitride semiconductor stack has a roughness between 3 nm and 500 nm.

13. The nitride light emitting device of claim 10 wherein the second rough surface of the second nitride semiconductor stack has a roughness between 3 nm and 500 nm.

14. The nitride light emitting device of claim 4 wherein the first transparent conductive layer comprises at least one material selected from a group consisting of Al, Ti, Ti/Al, Cr/Al, Ti/Au, Cr/Au, Ni/Au, TiW, TiN, WSi, Au/Ge, indium tin oxide, cadmium tin oxide, antimony tin oxide, zinc aluminum oxide, and zinc tin oxide.

15. The nitride light emitting device of claim 5 wherein the first transparent conductive layer comprises at least one material selected from a group consisting of Al, Ti, Ti/Al, Cr/Al, Ti/Au, Cr/Au, Ni/Au, TiW, TiN, WSi, Au/Ge, indium tin oxide, cadmium tin oxide, antimony tin oxide, zinc aluminum oxide, and zinc tin oxide.

16. The nitride light emitting device of claim 9 wherein the second transparent conductive layer comprises at least one material selected from a group consisting of Ni/Au, NiO/Au, TA/Au, TiWN, TiN, indium tin oxide, cadmium tin oxide, antimony tin oxide, zinc aluminum oxide, and zinc tin oxide.

17. The nitride light emitting device of claim 1 wherein the substrate comprises at least one material selected from a group consisting of sapphire, CaN, AlN, SiC, GaAs, GaP, Si, ZnO, MgO and glass.

18. The nitride light emitting device of claim 1 wherein the first nitride semiconductor stack comprises at least one material selected from a group consisting of AlN, GaN, AlGaN, InGaN, and AlInGa.

19. The nitride light emitting device of claim 1 wherein the nitride emitting layer comprises at least one material selected from a group consisting of AlN, GaN, AlGaN, InGaN, and AlInGaN.

20. The nitride light emitting device of claim 1 wherein the second nitride semiconductor stack comprises at least one material selected from a group consisting of AlN, GaN, AlGaN, InGaN, and AlInGa.

21. The nitride light emitting device of claim 2 wherein the first nitride contact layer comprises at least one material selected from a group consisting of AlN, GaN, AlGaN, InGaN, and AlInGaN.

22. The nitride light emitting device of claim 1 wherein the first nitride semiconductor stack is N-type and the second nitride semiconductor stack is P-type.

23. The nitride light emitting device of claim 1 wherein the first nitride semiconductor stack is P-type and the second nitride semiconductor stack is N-type.

24. A nitride light emitting device comprising:
a substrate;
a first nitride semiconductor stack formed above the substrate, the first nitride semiconductor stack having an epitaxial surface and a first rough surface, a distance from the epitaxial surface to the substrate being not less than a distance from the first rough surface to the substrate;
a nitride emitting layer formed on the epitaxial surface; and
a second nitride semiconductor stack formed on the nitride emitting layer and having a second rough surface.

25. The nitride light emitting device of claim 24 wherein the first nitride semiconductor stack comprises a nitride buffer layer formed on the substrate, and a first nitride contact layer formed on the nitride buffer layer.

26. The nitride light emitting device of claim 24 further comprising a first electrode formed above a first contact area of the first nitride semiconductor stack.

27. The nitride light emitting device of claim 26 wherein the distance between the first contact area and the substrate is longer than the distance between the first rough surface and the substrate.

28. The nitride light emitting device of claim 26 wherein the distance between the first contact area and the substrate is less than the distance between the first rough surface and the substrate.

29. The nitride light emitting device of claim 26 wherein the distance between the first contact area and the substrate is equal to the distance between the first rough surface and the substrate.

30. The nitride light emitting device of claim 26 further comprising a first transparent conductive layer formed between the first contact area and the first electrode.

31. The nitride light emitting device of claim 24 further comprising a first transparent conductive layer formed on the first contact area and the rough surface of the first nitride semiconductor stack.

32. The nitride light emitting device of claim 24 wherein the second nitride semiconductor stack has a second contact area.

33. The nitride light emitting device of claim 32 further comprising a second electrode formed above the second contact area of the second nitride semiconductor stack.

34. The nitride light emitting device of claim 33 further comprising a second transparent conductive layer between the second contact area and the second electrode.

35. The nitride light emitting device of claim 24 further comprising a reverse tunneling contact layer formed on the second nitride semiconductor stack, the reverse tunneling contact layer and the second nitride semiconductor stack being formed by opposite types of conductivity.

36. The nitride light emitting device of claim 35 wherein the reverse tunneling contact layer has a super lattice structure.

37. The nitride light emitting device of claim 24 further comprising a second transparent conductive layer formed on the second nitride * semiconductor stack.

38. The nitride light emitting device of claim 37 wherein the second transparent conductive lay has a second electrode.

39. The nitride light emitting device of claim 24 wherein the second rough surface of the second nitride semiconductor stack has a roughness between 3 nm and 500 nm.

40. The nitride light emitting device of claim 30 wherein the first transparent conductive layer comprises at least one material selected from a group consisting of Al, Ti, Ti/Al, Cr/Al, Ti/Au, Cr/Au, Ni/Au, TiW, TiN, WSi, Au/Ge, indium tin oxide, cadmium tin oxide, antimony tin oxide, zinc aluminum oxide, and zinc tin oxide.

41. The nitride light emitting device of claim 31 wherein the first transparent conductive layer comprises at least one material selected from a group consisting of Al, Ti, Ti/Al, Cr/Al, Ti/Au, Cr/Au, Ni/Au, TiW, TiN, WSi, Au/Ge, indium tin oxide, cadmium tin oxide, antimony tin oxide, zinc aluminum oxide, and zinc tin oxide.

42. The nitride light emitting device of claim 34 wherein the second transparent conductive layer comprises at least one material selected from a group consisting of Ni/Au, NiO/Au, Ta/Au, TiWN, TiN, indium tin oxide, cadmium tin oxide, antimony tin oxide, zinc aluminum oxide, and zinc tin oxide.

43. The nitride light emitting device of claim 37 wherein the second transparent conductive layer comprises at least one material selected from a group consisting of Ni/Au, NiO/Au, Ta/Au, TiWN, TiN, indium tin oxide, cadmium tin oxide, antimony tin oxide, zinc aluminum oxide, and zinc tin oxide.

44. The nitride light emitting device of claim 24 wherein the substrate comprises at least one material selected from a group consisting of sapphire, GaN, AlN, SiC, GaAs, GaP, Si, ZnO, MgO and glass.

45. The nitride light emitting device of claim 24 wherein the first nitride semiconductor stack comprises at least one material selected from a group consisting of AlN, GaN, AlGaN, InGaN, and AlInGaN.

46. The nitride light emitting device of claim 24 wherein the nitride emitting layer comprises at least one material selected from a group consisting of AlN, GaN, AlGaN, InGaN, and AlInGaN.

47. The nitride light emitting device of claim 24 wherein the second nitride semiconductor stack comprises at least one material selected from a group consisting of AlN, GaN, AlGaN, InGaN, and AlInGa.

48. The nitride light emitting device of claim 25 wherein the first nitride contact layer comprises at least one material selected from a group consisting of AlN, GaN, AlGaN, InGaN, and AlInGaN.

49. The nitride light emitting device of claim 24 wherein the first nitride semiconductor stack is N-type and the second nitride semiconductor stack is P-type.

50. The nitride light emitting device of claim 24 wherein the first nitride semiconductor stack is P-type and the second nitride semiconductor stack is N-type.

51. The nitride light emitting device of claim 24 wherein the second rough surface is formed by performing a dry etching process.

52. The nitride light emitting device of claim 51 wherein the dry etching process is a sputtering etching, ion-beam etching, plasma etching, or inactive ion etching process.

53. The nitride light emitting device of claim 24 wherein the second rough surface is an epitaxial surface.

54. A method for forming a nitride light emitting device comprising following steps:
(a) forming a substrate;
(b) forming a first nitride semiconductor stack above the substrate, the first nitride semiconductor stack having an epitaxial surface and a first rough surface, a distance from the epitaxial surface to the substrate being not less than a distance from the rough surface to the substrate;
(c) forming a nitride emitting layer on the epitaxial surface; and
(d) forming a second nitride semiconductor stack on the nitride emitting layer.

55. The method of claim 54 wherein step (b) comprises forming a nitride buffer layer on the substrate, and forming a first nitride contact layer on the nitride buffer layer.

56. The method of claim 54 further comprising forming a first electrode above a first contact area of the first nitride semiconductor stack.

57. The method of claim 54 further comprising forming a first transparent conductive layer between the first contact area and the first electrode.

58. The method of claim 54 further comprising forming a first transparent conductive layer on the first contact area and the rough surface of the first nitride semiconductor stack.

59. The method of claim 54 wherein a roughness of the first contact area is not greater than a roughness of the first rough surface.

60. The method of claim 54 further comprising forming a reverse tunneling contact layer on the second nitride semiconductor stack, the reverse tunneling contact layer and the second nitride semiconductor stack being formed by opposite types of materials.

61. The method of claim 60 wherein the reverse tunneling contact layer has a super lattice structure.

62. The method of claim 60 further comprising forming a second transparent conductive layer on the reverse tunneling contact layer.

63. The method of claim 54 further comprising forming a second rough surface and a second contact area on the second nitride semiconductor stack.

64. The method of claim 63 further comprising forming a second electrode above the second contact area of the second nitride semiconductor stack.

65. The method of claim 54 wherein the first rough surface of the first nitride semiconductor stack has a roughness between 3 nm and 500 nm.

66. The method of claim 63 wherein the second rough surface is formed by performing a dry etching process.

67. The method of claim 66 wherein the dry etching process is a sputtering etching, ion-beam etching, plasma etching, or inactive ion etching process.

68. The method of claim 63 wherein the second rough surface is an epitaxial surface.

69. The method of claim 54 wherein the first rough surface is formed by performing a dry etching process.

70. The method of claim 69 wherein the dry etching process is a sputtering etching, ion-beam etching, plasma etching, or inactive ion etching process.

71. The method of claim 54 wherein the first rough surface is formed by performing a wet etching process.
